(19) United States
(12) Patent Application Publication
(10) Pub. No.: US 2018/0351118 A1
(43) Pub. Date: Dec. 6, 2018

(54) DISPLAY DEVICE

(71) Applicant: Japan Display Inc., Minato-ku (JP)

(72) Inventor: Hiroki Nakaie, Minato-ku (JP)

(73) Assignee: Japan Display Inc., Minato-ku (JP)

(21) Appl. No.: 15/985,739

(22) Filed: May 22, 2018

(30) Foreign Application Priority Data
Jun. 6, 2017 (JP) 2017-111648

(51) Int. Cl. H01L 51/00; H01L 27/32; H01L 51/56

(52) U.S. Cl. CPC H01L 51/0097; H01L 27/3262; H01L 27/3265; H01L 27/1218; H01L 51/003; H01L 2251/5338; H01L 51/56

(57) ABSTRACT

A display device includes a resin layer having a first surface and second surface; an inorganic layer laminated on and in contact with the first surface; and a circuit layer on the inorganic layer, having a circuit to display images on a display area, and having a peripheral area outside the display area. The resin layer, the inorganic layer, and the circuit layer curve with the resin layer inside. The resin layer on the first surface has a recess extending to both ends, in a development view. The inorganic layer has a curved portion to be convex along a surface of the recess and in a depth direction of the recess, in a development view. The resin layer at the recess curves with the first surface outside. The inorganic layer at the curved portion curves with a concave surface of the curved portion outside.

### CROSS-REFERENCE TO RELATED APPLICATION

The present application claims priority from Japanese application JP2017-111648 filed on Jun. 6, 2017, the content of which is hereby incorporated by reference into this application.

### BACKGROUND OF THE INVENTION

### 1. Field of the Invention

This relates to display devices.

### 2. Description of the Related Art

Recently, to downsize a display device or magnify a display area, a frame area, which is around the display area to display images, is required to be narrower (slim bezel). The frame area has wirings and circuits provided therein. Specifically, the requirement for the slim bezel of mobile devices such as smartphones has become fierce. However, almost no idea is left for the slim bezel, requiring another way to respond.

JP 2010-256660A discloses how to bend a flexible display. The flexible display may have a substantially slim bezel, with its frame area folded to the backside. JP 2010-098645A discloses a flexible display having a circuit layer and an organic electroluminescence layer on a flexible resin substrate.

The processes of forming the circuit layer on the resin substrate generally include forming a base film, which is an inorganic insulation layer such as SiN or SiO, to prevent moisture intrusion or contamination from the resin substrate. However, the inorganic insulation layer is relatively hard and easy to be cracked when the resin substrate is bent, raising a problem of the breaking of wirings formed thereon.

### SUMMARY OF THE INVENTION

This is to aim at curbing damages of the inorganic layer laminated on the resin substrate.

A display device may include a resin layer having a first surface and second surface opposite to each other; an inorganic layer laminated on and in contact with the first surface of the resin layer; and a circuit layer laminated on the inorganic layer, having a circuit to display images on a display area, and having a peripheral area outside the display area. The resin layer, the inorganic layer, and the circuit layer curve with the resin layer inside. The resin layer on the first surface has a recess extending to both ends opposite to each other, in a development view, with the resin layer spread to be flat. The inorganic layer has a curved portion to be convex along a surface of the recess and in a depth direction of the recess, in a development view, with the inorganic layer spread to be flat. The resin layer at the recess curves with the first surface outside. The inorganic layer at the curved portion curves with a concave surface of the curved portion outside.

The inorganic layer has an outer surface. The outer surface is easy to be cracked when the inorganic layer is bent but is a concave surface in a development view with the inorganic layer spread to be flat, curbing damages of the inorganic layer.

### BRIEF DESCRIPTION OF THE DRAWINGS

FIG. 1 is a perspective view of a display device in accordance with an embodiment.

FIG. 2 is an enlarged view of a portion of II-II line cross section of the display device in FIG. 1.

FIG. 3 is a plan view of the display device in a pre-bent shape.

FIG. 4 is an enlarged view of a portion of IV-IV line cross section of the display device in FIG. 3.

FIGS. 5A-5D are diagrams to explain manufacturing methods of the display device in accordance with the embodiment.

FIG. 6 is a diagram to explain a variation 1 of the display device in accordance with the embodiment.

FIG. 7 is a diagram to explain a variation 2 of the display device in accordance with the embodiment.

FIG. 8 is a diagram to explain a variation 3 of the display device in accordance with the embodiment.

### DETAILED DESCRIPTION OF THE INVENTION

Hereinafter, embodiments will be described with reference to the drawings. Here, the invention can be embodied according to various aspects within the scope of the invention without departing from the gist of the invention and is not construed as being limited to content described in the embodiments exemplified below.

The drawings are further schematically illustrated in widths, thickness, shapes, and the like of units than actual forms to further clarify description in some cases but are merely examples and do not limit interpretation of the invention. In the present specification and the drawings, the same reference numerals are given to elements having the same functions described in the previously described drawings and the repeated description will be omitted.

Further, in the detailed description, “on” or “under” in definition of positional relations of certain constituents and other constituents includes not only a case in which a constituent is located just on or just under a certain constituent but also a case in which another constituent is interposed between constituents unless otherwise mentioned.

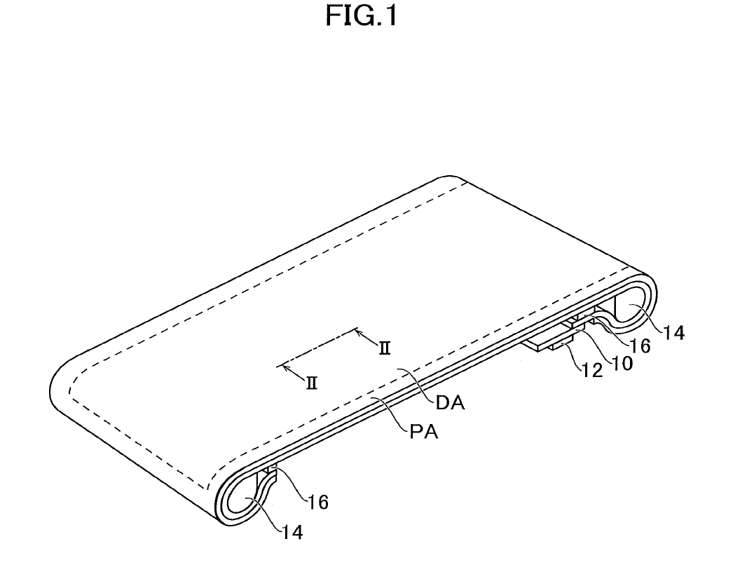

FIG. 1 is a perspective view of a display device in accordance with an embodiment. The display device is an organic electroluminescence display device. The display device is configured to display a full-color image in full-color pixels, each of which consists of combination of unit pixels (subpixels) of colors such as red, green, and blue. The display device includes a display area DA and a peripheral area PA around the display area DA. The peripheral area PA is outside the display area DA. A flexible printed circuit board 10 is connected to the peripheral area PA. On the flexible printed circuit board 10 is mounted an integrated circuit chip 12 for driving elements to display the image.

The display device curves at an end (e.g. both ends). FIG. 1 shows that the display area DA has an elongated shape such as a rectangle oblong in one direction and that the display area DA curves at at least one of both end portions in a longer direction, although the display area DA may curve at at least one of both end portions in a shorter direction. FIG. 1 shows that not only the peripheral area PA but also the display area DA at its end portion curve, although only the peripheral area PA may curve without bending the display area DA. Inside the curve is a spacer 14 to restrict curvature not to be too large. To keep the curve, the end portion is fixed with adhesive 16 inside the curve.

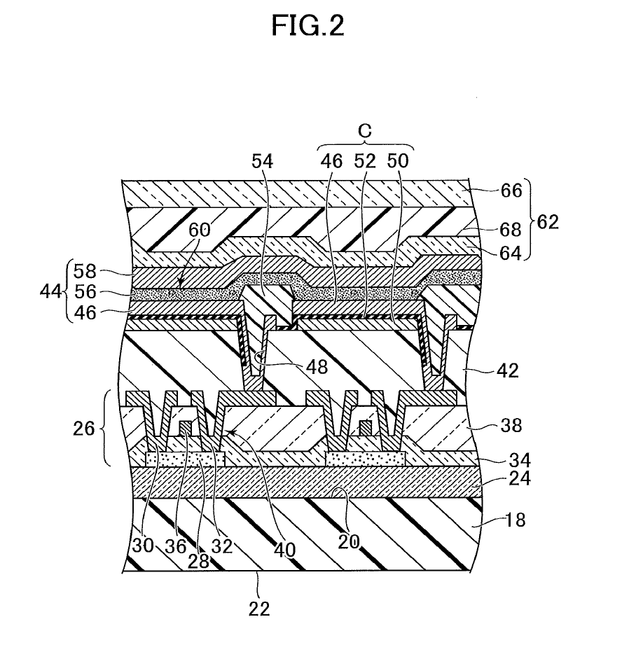

FIG. 2 is an enlarged view of a portion of II-II line cross section of the display device in FIG. 1. A resin layer 18 may be made from a polyimide resin or polyethylene terephthalate, having flexibility. The resin layer 18 has a first surface 20 and a second surface 22 opposite to each other. The resin layer 18 has an inorganic layer 24 formed thereon for a barrier against impurities contained therein. An inorganic layer 24 is laminated on and in contact with the first surface 20 of the resin layer 18. The inorganic layer 24 may be a silicon oxide film or a silicon nitride film or may be a laminate structure thereof.

On the inorganic layer 24 is laminated a circuit layer 26. The circuit layer 26 includes a circuit for displaying images in the display area DA. Specifically, in the circuit layer 26 on the inorganic layer 24 is a semiconductor layer 28. The semiconductor layer 28 is electrically connected to a source electrode 30 and a drain electrode 32. The semiconductor layer 28 is covered with a gate insulation film 34. On the gate insulation film 34 is a gate electrode 36, which is covered with an interlayer dielectric 38. The source electrode 30 and the drain electrode 32 penetrate the gate insulation film 34. The source electrode 30 and the drain electrode 32 in the display area DA are just on the interlayer dielectric 38 and penetrate the interlayer dielectric 38.

The semiconductor layer 28, the source electrode 30, the drain electrode 32, the gate electrode 36, and the gate insulation film 34 constitute at least one of a thin film transistor 40. The thin film transistor 40 is in the display area DA. The gate electrode 36 in the display area DA is just on the gate insulation film 34. The thin film transistor 40 is covered with a planarization film 42. The planarization film 42 is formed from an organic material such as a polyimide resin or a photosensitive acrylic resin.

On the planarization film 42 is a light emitting element layer 44. The light emitting element layer 44 includes a plurality of pixel electrodes 46 (e.g. anodes) for the respective unit pixels (subpixels). The pixel electrode 46 has a laminate structure of an electrode film and a light reflective film. The pixel electrode 46 is electrically connected to one of the source electrode 30 and the drain electrode 32 on the interlayer dielectric 38, through a contact hole 48 penetrating the planarization film 42.

The pixel electrode 46 is also one electrode of a capacitor C. The capacitor C is configured to include the pixel electrode 46, a capacity electrode 50 thereunder, and a dielectric insulation film 52 between the pixel electrode 46 and the capacity electrode 50. The capacitor C holds a signal for controlling a current to be supplied to the pixel electrode 46.

On the pixel electrode 46 is an insulation layer 54, which may be made from a polyimide resin or an acrylic resin. The insulation layer 54 is on the pixel electrode 46 at its periphery and is formed to expose a portion (e.g. central portion) of the pixel electrode 46. The insulation layer 54 constitutes a bank around the portion of the pixel electrode 46.

The light emitting element layer 44 includes an organic electroluminescence layer 56. The organic electroluminescence layer 56 is on the plurality of pixel electrodes 46, including a hole injection layer, a hole transport layer, a light emitting layer, an electron transport layer, and an electron injection layer. The light emitting layers are individually disposed (separated) from one another for the respective pixel electrodes 46 to emit light in red, green, or blue in the respective pixels. The color of each pixel is not limited thereto and may be yellow or white. Some layers included in the organic electroluminescence layer 56, except for the light emitting layer, entirely cover the display area DA (FIG. 1) to cover the plurality of pixels. The organic electroluminescence layer 56 is continuous on the insulation layer 54 as well.

The light emitting element layer 44 includes a common electrode 58 (e.g. cathode). The common electrode 58 is on the organic electroluminescence layer 56 and on the insulation layer 54, which is the bank. The pixel electrode 46 and the common electrode 58 with the organic electroluminescence layer 56 therebetween constitute at least a part of the light emitting element 60. The organic electroluminescence layer 56 lies between the pixel electrode 46 and the common electrode and emits light with its brightness controlled by a current flowing through them. The emitting elements 60 are in the display area DA and are driven with the respective thin film transistors 40. The capacitor C is provided for each of the light emitting elements 60.

The light emitting element layer 44 (specifically organic electroluminescence layer 56) is sealed with a sealing film 62 to be blocked from moisture. The light emitting elements 60 are sealed with the sealing film 62. The sealing film 62 has a structure where at least one organic layer 68 made from a material such as a resin is interposed between a pair of inorganic films 64, 66 made from material such as silicon nitride. The sealing film 62 covers the display area DA (FIG. 1). On the sealing film 62 may be laminated, not illustrated, an organic protective film, a circularly polarizing plate, and a cover film, with an adhesive layer interposed therebetween.

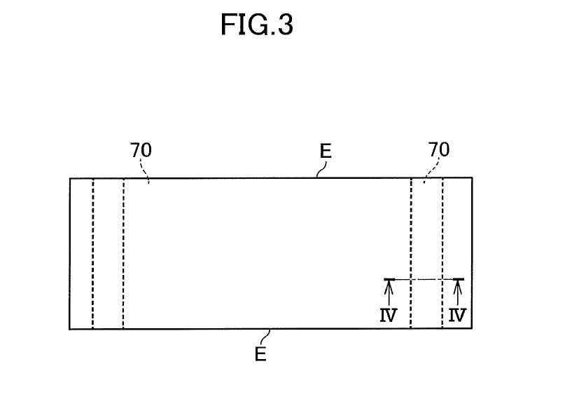

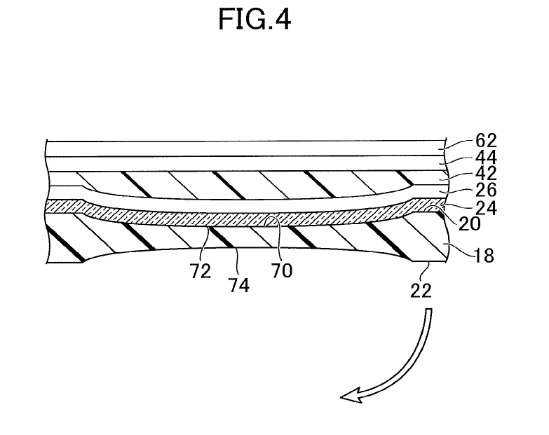

FIG. 3 is a plan view of the display device in a pre-bent shape. FIG. 4 is an enlarged view of a portion of IV-IV line cross section of the display device in FIG. 3.

The resin layer 18 on the first surface 20, in a pre-bent shape to be flat, has a first recess 70 extending to both ends E opposite to each other. The first recess 70 is formed with a concave surface. The inorganic layer 24, in a pre-bent shape to be flat, has a curved portion 72 that curves along the surface of the first recess 70 to be convex in a depth direction of the first recess 70. The curved portion 72 has a convex surface on a convex side and a concave surface on a concave side. The resin layer 18 on the second surface 22, in a pre-bent shape to be flat, has a second recess 74 extending to both ends opposite to each other. The first recess 70 overlaps with the second recess 74. The second recess 74 has a shape applied from the first recess 70.

The display device in FIG. 1 has a laminate including the resin layer 18, the inorganic layer 24, and the circuit layer 26. The laminate curves with the resin layer 18 inside as shown by an arrow in FIG. 4. The resin layer 18 curves at the first recess 70 with the first surface 20 outside. The inorganic layer 24 curves at the curved portion 72 with its concave surface outside. According to the embodiment, the inorganic layer 24 has an outer surface. The outer surface is easy to be cracked when the inorganic layer 24 is bent but is a concave surface in a development view with the inorganic layer 24 spread to be flat, curbing damages of the inorganic layer 24.

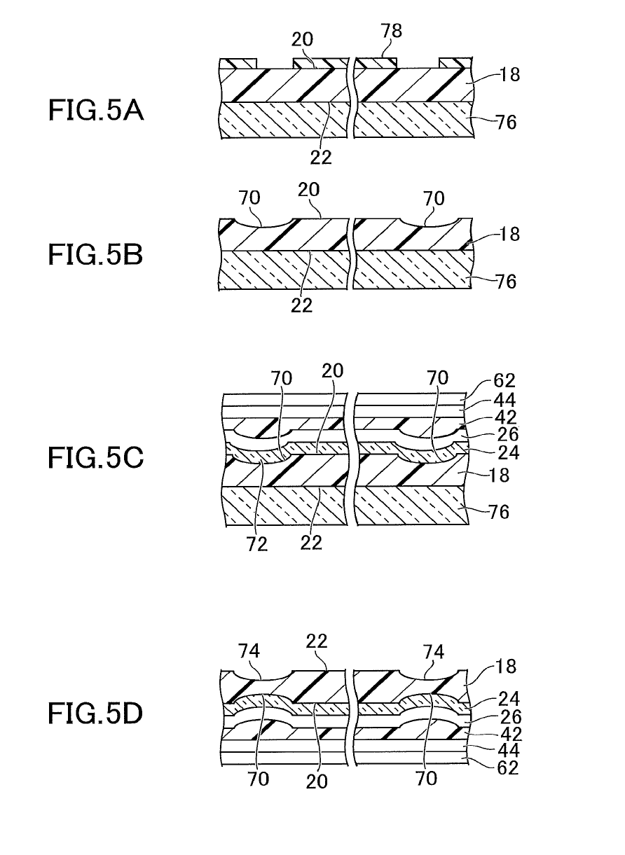

FIGS. 5A-5D are diagrams to explain manufacturing methods of the display device in accordance with the embodiment

As shown in FIG. 5A, a resin layer 18 may be formed from a polyimide resin on a glass substrate 76 and the resin layer 18 is etched using an etching mask 78. The etching mask 78 is formed from a photoresist through patterning by photolithography.

As shown in FIG. 5B, a first recess 70 is formed on the first surface 20 of the resin layer 18. Forming the first recess 70 includes etching. The concave surface is easy to be formed by applying isotropic etching. The etching mask 78 is removed after the etching.

As shown in FIG. 5C, the inorganic layer 24 may be formed from a silicon oxide film or a silicon nitride film on the first surface 20 of the resin layer 18. Forming the inorganic layer 24 may include chemical vapor deposition (CVD) or vapor deposition. Or, application of liquid material may improve coatability (coverage). On the inorganic layer 24 may be laminated the circuit layer 26, the planarization film 42, the light emitting element layer 44, and the sealing layer.

As shown in FIG. 5D, the glass substrate 76 is removed from the second surface 22 of the resin layer 18, forming the second recess 74 on the second surface 22. The forming process of the first recess 70 may be applied to the forming process of the second recess 74. An unillustrated protective film may be attached on the second surface 22, if necessary.

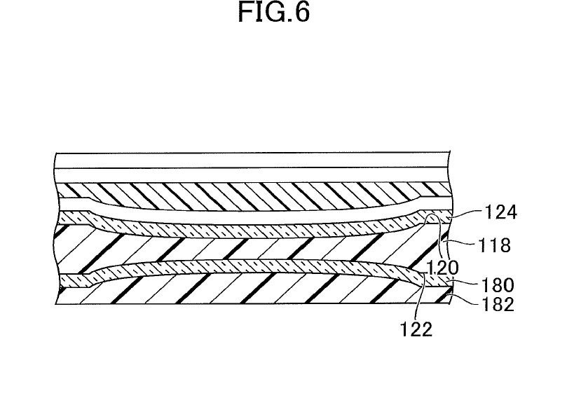

FIG. 6 is a diagram to explain a variation 1 of the display device in accordance with the embodiment. In this example, a second inorganic layer 180 is laminated on the second surface 122, in addition to the first inorganic layer 124 on the first surface 120 of the first resin layer 118. The details of the first inorganic layer 124 and the second inorganic layer 180 may be derived from the inorganic layer 24 explained in the embodiment. A second resin layer 182 is laminated on the second inorganic layer 180. The first resin layer 118 and the second resin layer 182 may be derived from the resin layer 18 explained in the embodiment.

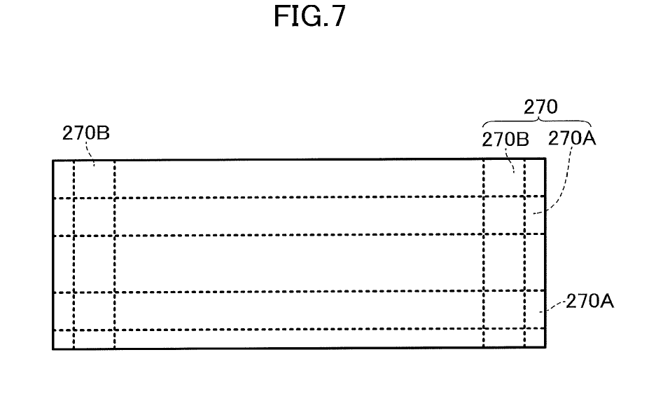

FIG. 7 is a diagram to explain a variation 2 of the display device in accordance with the embodiment. In this example, the resin layer has some recesses 270. The recesses 270 includes a pair of recesses 270A, 270B intersecting with each other. The resin layer has a rectangular planar shape. Each recess 270 extends along a side of the rectangle. For instance, the recess 270A extending along a longer side intersects with the recess 270B extending along a shorter side. The recesses 270 are in a grid pattern. One of the pair of recesses 270A, 270B may be selected to bend the resin layer.

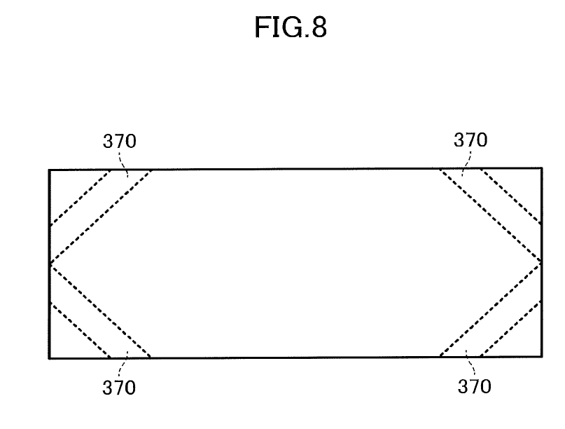

FIG. 8 is a diagram to explain a variation 3 of the display device in accordance with the embodiment. In this example, the resin layer has some recesses 370. The recesses 370 include at least a pair of recesses 370 extending in directions intersecting with each other. The pair of recesses 370 extend in directions intersecting with every side of the rectangle, which is a planar shape of the resin layer. One of the pair of recesses 370 may be selected to bend the resin layer.

The display device is not limited to the organic electroluminescence display device but may be a display device with a light-emitting element disposed in each pixel, such as a quantum-dot light-emitting diode (QLED).

While there have been described what are at present considered to be certain embodiments, it will be understood that various modifications may be made thereto, and it is intended that the appended claims cover all such modifications as fall within the true spirit and scope of the invention.

What is claimed is:

1. A display device comprising:
a resin layer having a first surface and second surface opposite to each other;
an inorganic layer laminated on and in contact with the first surface of the resin layer; and
a circuit layer laminated on the inorganic layer, having a circuit to display images on a display area, and having a peripheral area outside the display area, wherein
the resin layer, the inorganic layer, and the circuit layer curve with the resin layer inside,
the resin layer on the first surface has a recess extending to both ends opposite to each other, in a development view, with the resin layer spread to be flat,
the inorganic layer has a curved portion to be convex along a surface of the recess and in a depth direction of the recess, in a development view, with the inorganic layer spread to be flat,
the resin layer at the recess curves with the first surface outside, and
the inorganic layer at the curved portion curves with a concave surface of the curved portion outside.

2. The display device according to claim 1, wherein the resin layer on the second surface has a second recess extending to both ends opposite to each other, in a development view, with the resin layer spread to be flat.

3. The display device according to claim 2, wherein the recess on the first surface overlaps with the second recess on the second surface.

4. The display device according to claim 1, wherein the resin layer has some recesses including the recess.

5. The display device according to claim 4, wherein
the recesses include a pair of recesses intersecting with each other, and
the resin layer curves at one of the pair of recesses.

6. The display device according to claim 1, further comprising a second inorganic layer laminated on the second surface of the resin layer.

7. The display device according to claim 6, further comprising a second resin layer laminated under the second inorganic layer.
